(19) United States
(12) Patent Application Publication
(10) Pub. No.: US 2020/0014379 A1
(43) Pub. Date: Jan. 9, 2020

(54) Solid State Power Interrupter

(71) Applicant: INTELESOL, LLC, Danville, CA (US)

(72) Inventor: Mark TELEFUS, Orinda, CA (US)

(73) Assignee: INTELESOL, LLC, Danville, CA (US)

(21) Appl. No.: 16/029,549

(22) Filed: Jul. 7, 2018

(51) Int. Cl. H03K 17/082; H02H 3/08; H01R 13/703; H01L 27/02

(52) U.S. Cl. CPC H03K 17/082; H01L 27/0203; H01R 13/7038; H02H 3/08

(57) ABSTRACT

Power interruption device and/or method switches, controls, or otherwise interrupts one or more electrical signal, such as AC power or other electrical signal, applied to one or more load preferably via semiconductor or other solid state device, such as bipolar junction transistors (BJT), isolated gate bipolar transistor (IBJT), MOSFET, or other integrated circuit device. Advantageously such power interruption solution avoids conventional forced-based relay approaches, such as electromechanical relays, solid state relays, semiconductor control rectifiers (SCR), semiconductor triode for alternative current (TRIAC), etc., which are handicapped by limitations, including power carrying to the load, control mechanism, as well as size and inability to adapt to various signaling interfaces and communications. Preferred power interruption approach avoids electromechanical limitations, and thus offers improved speed, reliability, and functional versality to support various communication interfaces. For example, solid state power interrupter includes integrated circuit formed on semiconductor substrate, with switch embodied in circuit reconfigurable electronically to interrupt power signal coupled to switch from coupling to electrical load. Said circuit having one or more diode biased parasitically to cause power signal interruption, optionally in double pole single through (DPST) configuration, single pole single through (SPST) configuration, or double pole double through (DPDT) configuration. Optional pseudo airgap switch and/or interface coupled to the circuit for communicating with or controlling said switch.

### FIELD OF INVENTION

The invention pertains generally to the field of electrical power control circuits, and particularly to solid state power interrupters.

### BACKGROUND OF INVENTION

Conventional power control circuits for switching AC power lines rely electromechanically on forced-based relays, including solid state relays, semiconductor control rectifiers (SCR), semiconductor triode for alternative current (TRIAC), or other electromechanical relay devices. Such conventional relay-based approaches for controlling electrical power lines, however, are limited due to power carrying to the load, control mechanism, as well as size and inability to adapt to signaling interfaces and communications. There is need, therefore, for improved power interruption means that avoids conventional electromechanical limitations, thereby offering better speed, reliability, and functional versatility to support various communication interfaces.

### SUMMARY

Integrated circuit switches or otherwise controls electrically power connection to load on or off. Preferably, a solid state semiconductor device having parasitically bias-able diode(s) may electronically cause circuit interruption or non-interruption of electrical connectivity between an AC power line and electrical load(s). Device diodes may be embodied in bipolar junction transistors (BJT), isolated gate bipolar transistor (IBJT), metal oxide semiconductor field effect transistors (MOSFET), or other solid state devices. Moreover, solid state interrupter may be implemented using double pole single through (DPST) circuitry, optionally including a pseudo airgap switch. Also, solid state interrupter may be implemented using single pole single through (SPST) or double pole double through (DPDT) circuitry. Furthermore, interrupter circuitry may be integrated on-chip with digital interface for controlling, reconfiguring, toggling, communicating, signaling, monitoring, or otherwise accessing such circuitry.

For example, solid state power interrupter includes integrated circuit formed on semiconductor substrate, with switch embodied in circuit reconfigurable electronically to interrupt power signal coupled to switch from coupling to electrical load. Said circuit may use one or more diode biased parasitically to cause power signal interruption, optionally in double pole single through (DPST) configuration, single pole single through (SPST) configuration, or double pole double through (DPDT) configuration. Optional pseudo airgap switch and/or interface couples to the circuit for communicating with or controlling said switch.

### BRIEF DESCRIPTION OF FIGURES

FIGS. 1A-1B, 2, 3, 4, 5A and 5B illustrate embodiments according to various inventive aspects.

### DETAILED DESCRIPTION

Generally, one or more integrated circuit or other functionally equivalent solid state device or similarly integrated electronic module thereof interrupts, switches, toggles, or otherwise controls electrical signal or power conduction or transmission between one or more power source and one or more load, e.g., AC power line electrically coupled to load.

In particular, a solid state or semiconductor device or equivalent circuitry may include parasitically bias-able diode(s) or other equivalently bias able circuit element that serves functionally to cause circuit interruption or non-interruption effectively of electrical connectivity between AC power line(s) and corresponding electrical load(s).

Parasitically bias-able device diodes may be embodied in bipolar junction transistors (BJT), isolated gate bipolar transistor (IBJT), metal oxide semiconductor field effect transistors (MOSFET), or other solid state devices.

Moreover, as illustrated variously herein, solid state interrupter may be implemented using double pole single through (DPST) circuitry, optionally including a pseudo airgap switch; as well as single pole single through (SPST) or double pole double through (DPDT) circuitry. Furthermore, interrupter circuitry may be integrated on-chip with digital interface for controlling, reconfiguring, toggling, communicating, signaling, monitoring, or otherwise accessing such circuitry.

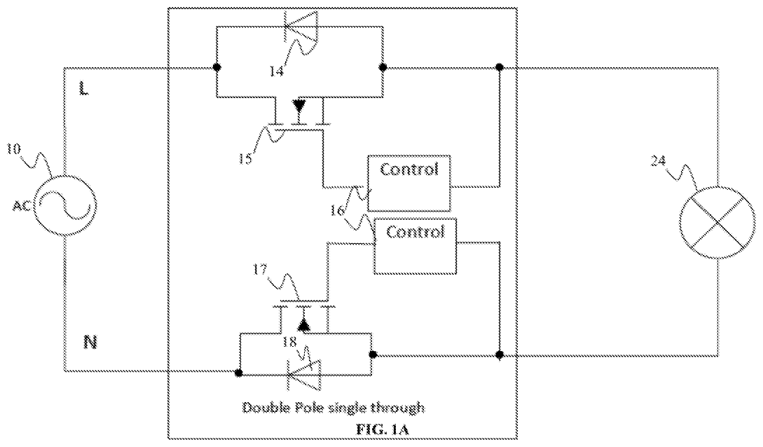

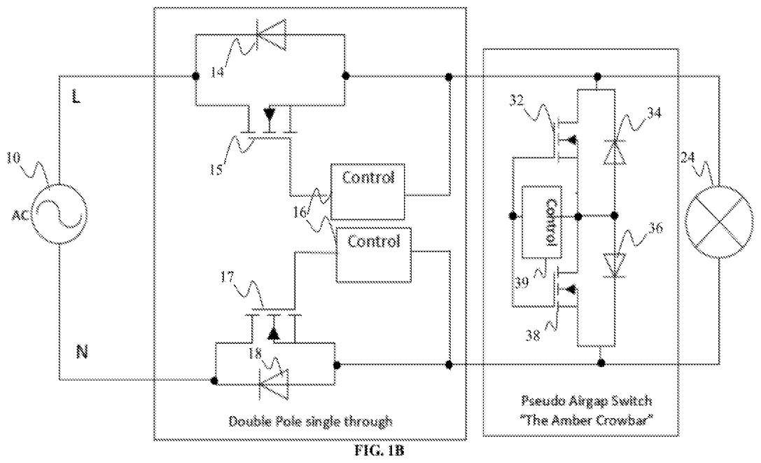

FIG. 1A shows solid state power interrupter apparatus embodied in double pole single through circuit configuration 12 for switching or interrupting AC signal source 10 connectivity to electrical load 20. As shown, parasitically bias-able diode 14 and transistor 15 couple to AC signal 10 and couple to load 20 and control 16; and parasitically bias-able diode 18 and transistor 17 couple to AC signal 10 and couple to load 20 and control 16. Thus, when receiving alternating voltage and/or current, such parasitically bias-able diode(s) serve to interrupt the AC signal source connectivity to electrical load 20. Preferably, such parasitically bias-able diode(s) further serve as current source for transistor(s) to generate DC gate drive.

FIG. 1B shows pseudo airgap switch coupled between AC signal source 10 and load 20 additionally to circuit of FIG. 1A. As shown, control 39 couples to transistor 32 and parasitically bias-able diode 34, and transistor 38 and parasitically bias-able diode 36. Thus, when AC signal source switches off, only leakage current is present in pseudo-airgap switch, thereby serving as crowbar shunt to ground. Preferably, such parasitically bias-able diode(s) further serve as current source for transistor(s) to generate DC gate drive.

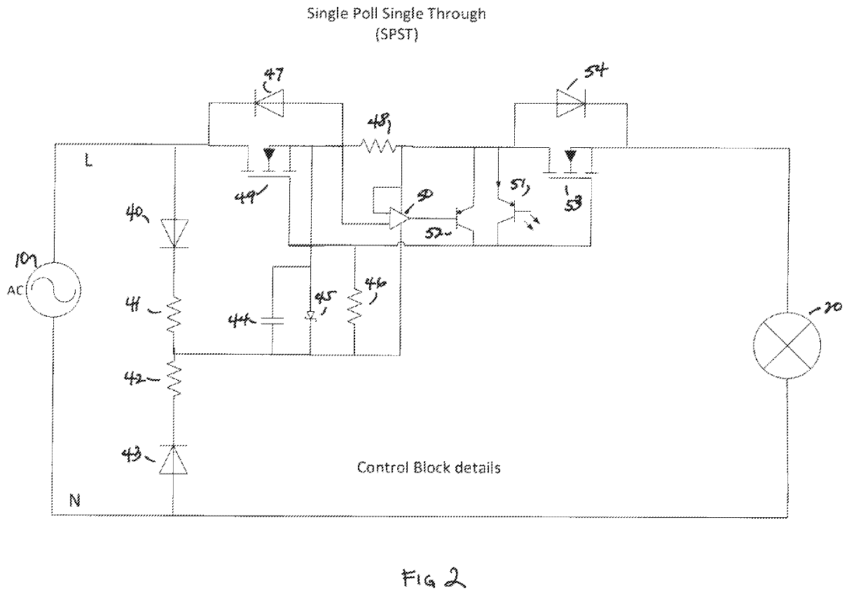

FIG. 2 shows single poll single through embodiment of solid state power interrupter apparatus. As shown, AC signal source 10 couples to parasitically bias-able diode 40, resistor 41, resistor 42, and parasitically bias-able diode 43; and parasitically bias-able diode 47 transistor 49, resistor 48, and parasitically bias-able diode 54 to load 20. Further, amp 50 couples to transistor 52, optical transistor sensor 51, and transistor 53; and capacitor couples to parasitically bias-able Zener diode 45, resistor 46. Thus, when receiving alternating voltage and/or current, such parasitically bias-able diode(s) serve to interrupt the AC signal source connectivity to electrical load 20. Preferably, such parasitically bias-able diode(s) further serve as current source for transistor(s) to generate DC gate drive.

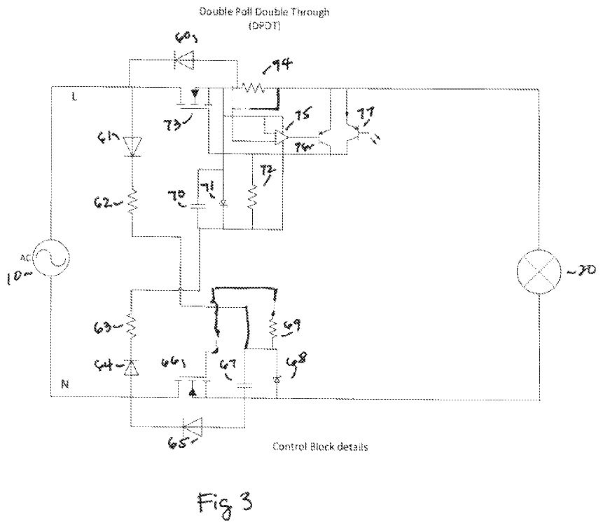

FIG. 3 shows double poll double through embodiment of solid state power interrupter apparatus. As shown, AC signal source 10 couples to parasitically bias-able diode 61, resistor 62, capacitor 67, parasitically bias-able diode 65, parasitically bias-able diode 64, resistor 63 transistor 66, resistor 69, parasitically bias-able Zener diode 68 to load 20; AC signal 10 further couples load 20 to diode 60, resistor 94, transistor 73, resistor 74, amp 75, transistor 76, optical transistor sensor 77, resistor 72, parasitically bias-able Zener diode 71, and capacitor 70. Thus, when receiving alternating voltage and/or current, such parasitically bias-able diode(s) serve to interrupt the AC signal source connectivity to electrical load 20. Preferably, such parasitically bias-able diode(s) further serve as current source for transistor(s) to generate DC gate drive.

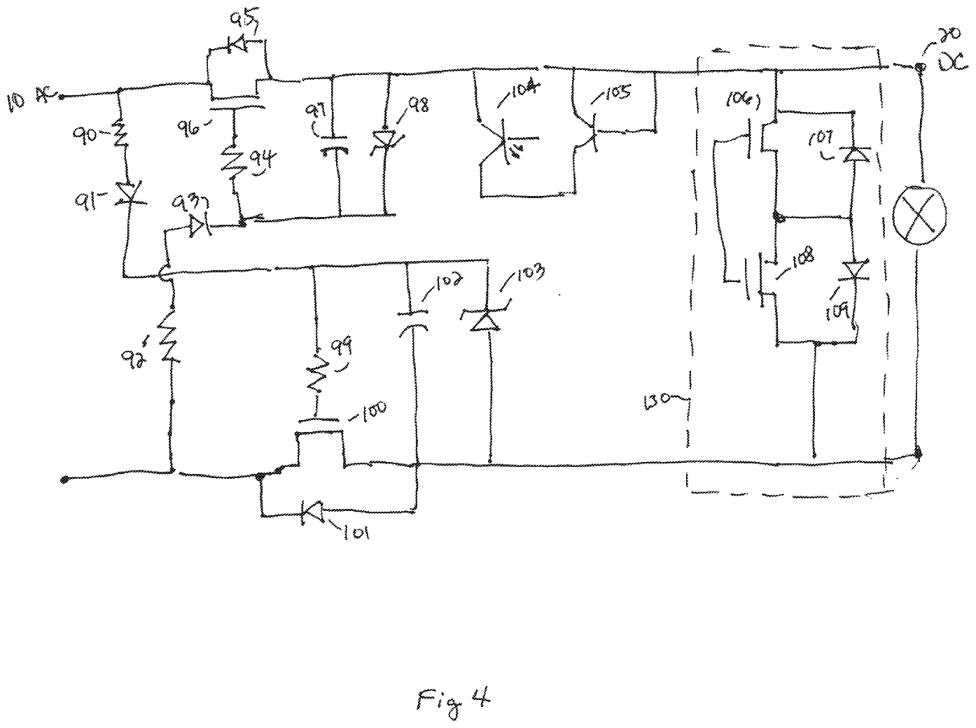

FIG. 4 shows preferred embodiment of solid state power interrupter apparatus. As shown, AC signal source 10 couples to resistor 90, parasitically bias-able diode 91, capacitor 102, diode 101, parasitically bias-able Zener diode 103, transistor 100, resistor 99, resistor 92, parasitically bias-able diode 93, resistor 94, transistor 96, parasitically bias-able diode 95, capacitor 97, parasitically bias-able Zener diode 98, optical transistor sensor 104, transistor 105; AC signal 10 further couples load 20 to pseudo airgap switch 130 including transistor 106, 108, parasitically bias-able diode 107, and parasitically bias-able diode 109. Thus, when receiving alternating voltage and/or current, such parasitically bias-able diode(s) serve to interrupt the AC signal source connectivity to electrical load 20. Also, when AC signal source switches off, only leakage current is present in pseudo-airgap switch, thereby serving as crowbar shunt to ground. Preferably, such parasitically bias-able diode(s) further serve as current source for transistor(s) to generate DC gate drive.

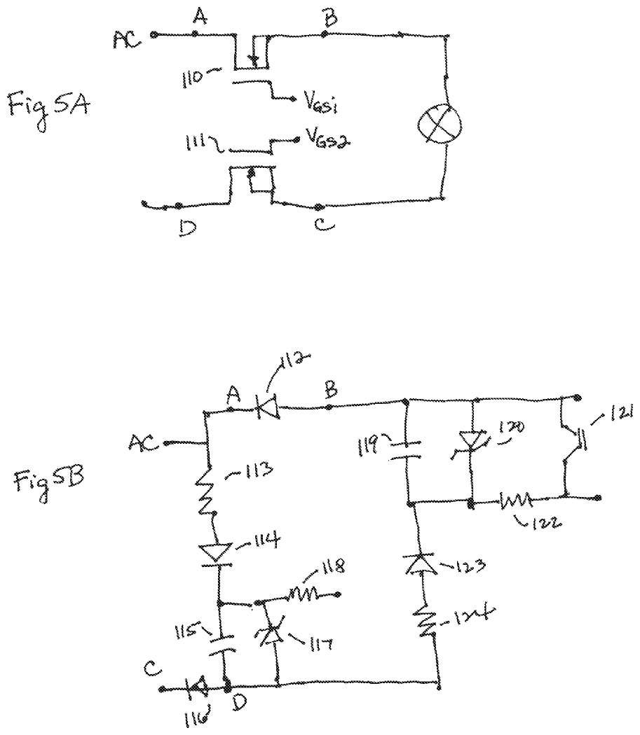

FIG. 5A shows one or more aspect of solid state power interrupter apparatus. As shown, AC signal source couples to load via transistors 110, 111. Thus, when receiving alternating voltage and/or current, such parasitically bias-able diode(s) serve to interrupt the AC signal source connectivity to electrical load. Preferably, such parasitically bias-able diode(s) further serve as current source for transistor(s) to generate DC gate drive.

FIG. 5B shows one or more aspect of solid state power interrupter apparatus. As shown, AC signal source couples to resistor 113, parasitically bias-able diode 114, capacitor 115, parasitically bias-able diode 116, parasitically bias-able Zener diode 117, resistor 118, capacitor 119, parasitically bias-able diode 123, resistor 124, parasitically bias-able Zener diode 120, resistor 122, and transistor 121. Thus, when receiving alternating voltage and/or current, such parasitically bias-able diode(s) serve to interrupt the AC signal source connectivity to electrical load. Preferably, such parasitically bias-able diode(s) further serve as current source for transistor(s) to generate DC gate drive.

Foregoing descriptions of specific embodiments of the invention have been presented for purposes of illustration and description. They are not intended to be exhaustive or to limit the invention to the precise forms disclosed. Modifications and variations are possible in light of the above teaching. The embodiments were chosen and described in order to explain the principles and the application of the invention, thereby enabling others skilled in the art to utilize the invention in its various embodiments and modifications according to the particular purpose contemplated. The scope of the invention is intended to be defined by the claims appended hereto and their equivalents.

1. Solid state power interrupter comprising:
an integrated circuit formed on a semiconductor substrate; and
a switch embodied in said circuit being reconfigurable electronically to interrupt an electrical power signal coupled to said switch from coupling further to an electrical load.

2. Interrupter of claim 1 wherein said circuit comprises one or more diode, such that at least one such diode is biased parasitically to cause said power signal interruption.

3. Interrupter of claim 1 wherein said circuit comprises a double pole single through (DPST) configuration.

4. Interrupter of claim 4 wherein said circuit further comprises a pseudo airgap switch.

5. Interrupter of claim 1 wherein said circuit comprises a single pole single through (SPST) configuration.

6. Interrupter of claim 1 wherein said circuit comprises a double pole double through (DPDT) configuration.

7. Interrupter of claim 1 further comprising interface means coupled to the circuit for communicating with or controlling said switch.

8. Solid state power interrupter method comprising steps:
coupling an electrical power signal source to an integrated circuit formed on a semiconductor substrate; and
electronically causing a switch embodied in said circuit to interrupt the electrical power signal from coupling to an electrical load.

9. Interrupter method of claim 8 wherein said circuit comprises one or more diode, such that at least one such diode is biased parasitically to cause said power signal interruption.

10. Interrupter method of claim 8 wherein said circuit comprises a double pole single through (DPST) configuration.

11. Interrupter method of claim 10 wherein said circuit further comprises a pseudo airgap switch.

12. Interrupter method of claim 8 wherein said circuit comprises a single pole single through (SPST) configuration.

13. Interrupter method of claim 8 wherein said circuit comprises a double pole double through (DPDT) configuration.

14. Interrupter method of claim 8 wherein interface means is coupled to the circuit for communicating with or controlling said switch.

15. Circuit for switching an AC power line coupled to an electrical load comprising:
a solid state circuit comprising one or more diode which is biased parasitically to cause said circuit to interrupt electrical connectivity between an AC power line and an electrical load.

16. Circuit of claim 15 wherein said circuit comprises a double pole single through (DPST) configuration.

17. Circuit of claim 16 wherein said circuit further comprises a pseudo airgap switch.

18. Circuit of claim 15 wherein said circuit comprises a single pole single through (SPST) configuration.

19. Circuit of claim 15 wherein said circuit comprises a double pole double through (DPDT) configuration.

20. Circuit of claim 15 wherein the circuit is network accessible for communicating with or controlling said circuit.
